(19) United States
(12) Patent Application Publication
(10) Pub. No.: US 2026/0155178 A1
(43) Pub. Date: Jun. 4, 2026

(54) MEMORY DEVICE AND AN OPERATION METHOD FOR IMPROVING A PROGRAM OPERATION

(71) Applicant: SK hynix Inc., Gyeonggi-do (KR)

(72) Inventors: Eun Woo JO, Gyeonggi-do (KR); Da U Ni KIM, Gyeonggi-do (KR)

(21) Appl. No.: 19/186,623

(22) Filed: Apr. 23, 2025

(30) Foreign Application Priority Data
Dec. 3, 2024 (KR) 10-2024-0177239

(51) Int. Cl. G11C 16/08; G11C 16/10

(52) U.S. Cl. CPC G11C 16/08; G11C 16/10

(57) ABSTRACT

A memory device includes a cell array and control circuitry. The cell array includes a plurality of cell strings coupled to a word line and a drain select line. The control circuitry is configured to apply a program voltage to the word line during a program time period, and control the drain select line to avoid programming data in plural memory cells included in the plurality of cell strings during a partial time length in the program time period.

### CROSS-REFERENCE TO RELATED APPLICATIONS

This patent application claims the benefit of priority under 35 U.S.C. § 119(a) to Korean Patent Application No. 10-2024-0177239, filed on Dec. 3, 2024, the entire disclosure of which is incorporated herein by reference.

### TECHNICAL FIELD

Various embodiments of the present disclosure described herein relate to a memory device, and more particularly, to a memory device performing an improved program operation and an operation method of the memory device.

### BACKGROUND

A computing system increases an amount of computation in response to user needs. As the amount of computation increases, an amount of data generated or stored also increases. A memory system in the computing system performs data input and output operations in response to a request from an external device such as a host. The memory system can include at least one memory device. The memory device can include at least one of a volatile memory cell and a non-volatile memory cell, for storing data.

### BRIEF DESCRIPTION OF THE DRAWINGS

The description herein makes reference to the accompanying drawings wherein like reference numerals refer to like parts throughout the figures.

FIG. 1 illustrates a first memory device according to an embodiment of the present disclosure.

FIG. 2 illustrates a second memory according to an embodiment of the present disclosure.

FIG. 3 illustrates a first cell array structure according to an embodiment of the present disclosure.

FIG. 4 illustrates a second cell array structure according to an embodiment of the present disclosure.

FIG. 5 illustrates a third cell array structure according to an embodiment of the present disclosure.

FIG. 6 illustrates a fourth cell array structure according to an embodiment of the present disclosure.

FIG. 7 illustrates a program operation and a verification operation according to an embodiment of the present disclosure.

FIG. 8 illustrates a program operation mode according to an embodiment of the present disclosure.

FIG. 9 illustrates a delay regarding a voltage or a signal applied to a cell array according to an embodiment of the present disclosure.

FIG. 10 illustrates a first program operation according to an embodiment of the present disclosure.

FIG. 11 illustrates a second program operation according to an embodiment of the present disclosure.

FIG. 12 illustrates a third program operation according to an embodiment of the present disclosure.

FIG. 13 illustrates a fourth program operation according to an embodiment of the present disclosure.

### DETAILED DESCRIPTION

Various embodiments of the present disclosure are described below with reference to the accompanying drawings. In this disclosure, elements and features may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, circuits, memory storing program instructions executable to implement the operation, etc. Additionally, “configured to” can include a generic structure, e.g., generic circuitry, that is manipulated by software and/or firmware, e.g., an FPGA or a general-purpose processor executing software to operate in a manner that is capable of performing the task(s) at issue. “Configured to” may also include adapting a manufacturing process, e.g., a semiconductor fabrication facility, to fabricate devices, e.g., integrated circuits that are adapted to implement or perform one or more tasks.

As used in this disclosure, the term ‘machine,’ ‘circuitry’ or ‘logic’ refers to all of the following: (a) hardware-only circuit implementations such as implementations in only analog and/or digital circuitry and (b) combinations of circuits and software and/or firmware, such as (as applicable): (i) to a combination of processor(s) or (ii) to portions of processor(s)/software including digital signal processor(s), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘machine,’ ‘circuitry’ or ‘logic’ applies to all uses of this term in this application, including in any claims. As a further example, as used in this application, the term ‘machine,’ ‘circuitry’ or ‘logic’ also covers an implementation of merely a processor or multiple processors or a portion of a processor and its (or their) accompanying software and/or firmware. The term ‘machine,’ ‘circuitry’ or ‘logic’ also covers, for example, and if applicable to a particular claim element, an integrated circuit for a storage device.

As used herein, the terms ‘first’, ‘second’, ‘third’, and so on are used as labels for nouns that they precede, and do not imply any type of ordering, e.g., spatial, temporal, logical, etc. The terms ‘first’ and ‘second’ do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term ‘based on’ is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Embodiments of the present disclosure can provide a memory device, a memory system including the memory device, or a data processing apparatus including the memory system.

An embodiment of the present disclosure can provide a memory device and an operating method of the memory device which is capable of reducing or avoiding a difference of valid or effective program time periods at memory cells apart from each other due to a delay of a voltage applied through a word line based on locations or positions of a plurality of cell strings included in the memory device.

In addition, an embodiment of the present disclosure can provide a memory device and a memory system including the memory device which is capable of identically adjusting an effective period during which data is programmed to a plurality of memory cells due to a program voltage applied through a word line regardless of locations or positions of the plurality of memory cells, thereby improving reliability of program and verification operations.

In an embodiment of the present disclosure, a memory device can include a cell array comprising a plurality of cell strings coupled to a word line and a drain select line; and control circuitry configured to apply a program voltage to the word line during a program time period, and control the drain select line to avoid programming data in plural memory cells included in the plurality of cell strings during a partial time length in the program time period.

The partial time length can include a delay time of the program voltage which reaches a second cell string farthest from the control circuit after applied through the word line.

The plurality of cell strings includes a first cell string closest to the control circuitry and a second cell string farthest from the control circuitry. Effective periods for programming the data in the first cell string and the second cell string can be substantially equal to each other.

Each effective period can be 50% or less of the program time period.

The control circuity can be configured to inactivate the drain select line during the partial time length.

The partial time length can be determined based on a number of the plurality of cell strings coupled to the word line.

The program voltage can have a voltage level greater than a pass voltage applied to other word lines adjacent to the word line. The control circuitry can be configured to apply the program voltage to the word line after applying the pass voltage to the other word lines.

The control circuitry can be configured to inactivate the drain select line while the pass voltage is applied.

The control circuitry can be configured to control the drain select line to avoid verifying the data programmed in the plural memory cells during a partial time period of a verification time period in which a verification voltage is applied to the word line.

In another embodiment, a method for operating a memory device can include applying a program voltage to a plurality of memory cells through a word line during a program time period; and controlling a drain select line to avoid programming data in the plurality of memory cells included in a plurality of cells strings during a partial time length in the program time period.

The plurality of cell strings includes a first cell string closest to the control circuitry and a second cell string farthest from the control circuitry. Effective periods for programming the data in the first cell string and the second cell string can be substantially equal to each other.

The partial time length can be determined based on a number of the plurality of cell strings coupled to the word line.

Controlling the drain select line can include inactivating the drain select line during the partial time length.

Applying the program voltage can include applying a pass voltage to plural word lines and inactivating the drain select line while the pass voltage is applied; and applying the program voltage to the word line selected among the plural word lines.

The method can further include applying a verification voltage to the word line; and controlling the drain select line to avoid verifying the data in the plurality of memory cells included in the plurality of cells strings during a partial time length in a verification time period in which the verification voltage is applied to the word line.

In another embodiment, a memory device can include a plurality of drain select lines individually coupled to each of a plurality of cell strings; at least one word line coupled to the plurality of cell strings; and control circuitry configured to apply a program voltage to the word line during a program time period, and control the plurality of drain select line to avoid programming data in plural memory cells included in the plurality of cell strings during a partial time length in the program time period.

The plurality of cell strings includes a first cell string closest to the control circuitry and a second cell string farthest from the control circuitry. Effective periods for programming the data in the first cell string and the second cell string can be substantially equal to each other.

The partial time length can be determined based on a number of the plurality of cell strings coupled to the word line.

In another embodiment, a memory device can include a plurality of word lines coupled to a plurality of cell strings; and control circuitry configured to select a word line among the plurality of word lines and apply a first voltage to at least one word adjacent line adjacent to the word line before applying a program voltage to the word line, the first voltage having a level greater than a pass voltage.

The at least one adjacent word line can include a first word line and a second word line, which is closer to the word line than the first word line. The control circuitry can be configured to apply the pass voltage to the second word line before applying the program voltage to the word line and during a preset time period after applying the program voltage to the word line; apply the first voltage to the first word line before applying the program voltage to the word line; and apply the pass voltage to the first word line during the preset time period.

These and other features and advantages of the invention will become apparent from the detailed description and the accompanying drawings of embodiments of the present disclosure. Embodiments will now be described with reference to the accompanying drawings, wherein like numbers reference like elements.

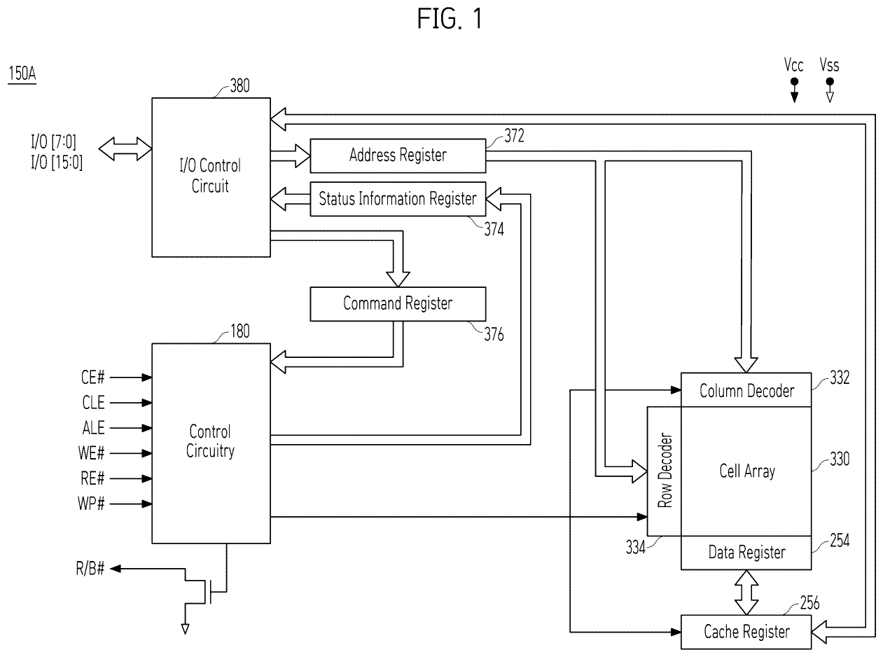

FIG. 1 illustrates a first memory device 150A according to an embodiment of the present disclosure.

Referring to FIG. 1, the first memory device 150A can include at least one memory die. The first memory device 150A can receive or output a plurality of control signals CE#, CLE, ALE, WE#, RE#, WP#, R/B#, and receive or transmit data or operation information through channels I/O[7:0], I/O[15:0]. For example, a predetermined amount of data (e.g., 1 byte (8 bits) or 2 bytes (16 bits)) can be transmitted and received according to a channel (e.g., I/O[7:0], I/O[15:0]) connecting the first memory device 150A and a controller.

According to an embodiment, the first memory device 150A can include a plurality of pins or pads. For example, the plurality of control signals CE#, CLE, ALE, WE#, RE#, WP#, R/B#can be transmitted or received through exclusively allocated pins. The control signals can include a chip enable signal CE#, a command latch enable signal CLE, an address latch enable signal ALE, a write enable signal WE#, a read enable signal RE#, a write protect signal WP#, a status signal R/B #indicating a ready state or a busy state, and the like. The control signals CE#, CLE, ALE, WE#, RE#, WP#, R/B#can be controlled (transmitted and received) by control circuitry 180 included in the first memory device 150A.

The first memory device 150A can include an input and output (input/output (I/O)) control circuit 380. The input/output control circuit 380 can be connected to other devices or components (e.g., a controller) through the channels I/O[7:0], I/O[15:0]. The input/output control circuit 380 in the first memory device 150A can be coupled to a plurality of registers 372, 374, 376 and a cache register 256 coupled to a cell array 330.

According to an embodiment, the input/output control circuit 380 can include a chip select decoder, while the first memory device 150A may include a plurality of memory chips. Chip select function may be used to activate one of the plurality of memory chips included in or connected to a memory system or a data processing system. Depending on the embodiment, the chip select decoder may be implemented with combinational logic gates that activate one specific output line in response to an input binary code. The memory system or the data processing system can use an activated output line to activate or “select” a specific chip or device from multiple devices connected to the memory system or the data processing system. For example, if there are multiple memory chips on a same bus (such as flash memory chips in solid state drives (SSDs)), for most operations it is impossible to communicate with all memory chips simultaneously because data entries or commands sent across the bus could be routed to all memory chips. Instead, a chip select signal can be used to select which chip to communicate with at any given time. The chip select decoder can manage and control data communication between multiple devices (e.g., the multiple memory chips) that share the same bus or connection lines in a system by activating one specific device based on an input select code or signal.

According to an embodiment, the first memory device 150A may include the cache register 256, an address register 372, a status information register 374, and a command register 376. The cache register 256 can temporarily store data. When the first memory device 150A performs a read operation, the cache register 256 can store a read data entry output from the cell array 330. When the first memory device 150A performs a write operation or a program operation, the cache register 256 can store a write data entry. The address register 372 can store an address indicating a location of the cell array 330 where a read operation or a write operation is to be performed. The command register 376 can store a command to be executed by the first memory device 150A. The status information register 374 can store status information such as a result (failure/success) of an operation performed in the first memory device 150A or readiness for performing an operation. For example, when a plurality of memory planes is included in a memory die in the first memory device 150A, the status information register 374 can store status information regarding each of the plurality of memory planes. Data, commands, and information transmitted or received through the input/output control circuit 380 in the first memory device 150A can be controlled (e.g., transmitted, moved, or output) by the control circuitry 180.

During a read operation in the first memory device 150A, a row decoder 334 and a column decoder 332 can select one or more memory cells in the cell array 330 based on an address stored in the address register 372 and a control signal from the control circuitry 180. During a read operation, a read data entry output from the cell array 330 may be stored in the data register 254 and then transferred from the data register 254 to the cache register 256. The read data entry stored in the cache register 256 is transferred to the input/output control circuit 380 through input/output lines. The read data entry transmitted to the input/output control circuit 380 can be output to the controller through the channels I/O[7:0], I/O[15:0].

During a write operation or a program operation in the first memory device 150A, the row decoder 334 and the column decoder 332 can select one or more memory cells in the cell array 330 in response to an address stored in the address register 372 and a control signal from the control circuitry 180. During the write operation, the write data entry transferred from the controller to the input/output control circuit 380 through the channels I/O[7:0], I/O[15:0] can be stored in the cache register 256. Thereafter, the write data entry can be transferred from the cache register 256 to the data register 254. The write data entry stored in the data register 254 can be programmed in selected memory cells in the cell array 330 by the control circuitry 180.

The data register 254 and the cache register 256 can be included in a read/write circuit comprising a sense amplifier, a page buffer, or the like. According to an embodiment, page buffers or data latches included in the first memory device 150A can correspond to the data register 254 and/or the cache register 256. Further, the cache register 256 is configured to temporarily store data transmitted between the data register 254 and the input/output control circuit 380. The cache register 256 may have a pipe latch structure depending on the embodiment.

A pipeline (or pipelining) system including at least one pipe latch can include an apparatus that can parallelize a plurality of data entries input and output serially. According to an embodiment, the pipeline system is applicable to the input/output control circuit 380 or the cache register 256. Further, according to an embodiment, the pipeline system may be used to compensate for delays and noise occurring in a data transmission process as a data path through which data is transmitted within the first memory device 150A of the memory system becomes longer.

The cell array 330 shown in FIG. 1 can have a two-dimensional or three-dimensional structure. Hereinafter, various structures of the cell array 330 and an operation for programming data or verifying programmed data in a plurality of memory cells included in the cell array 330 will be specifically described.

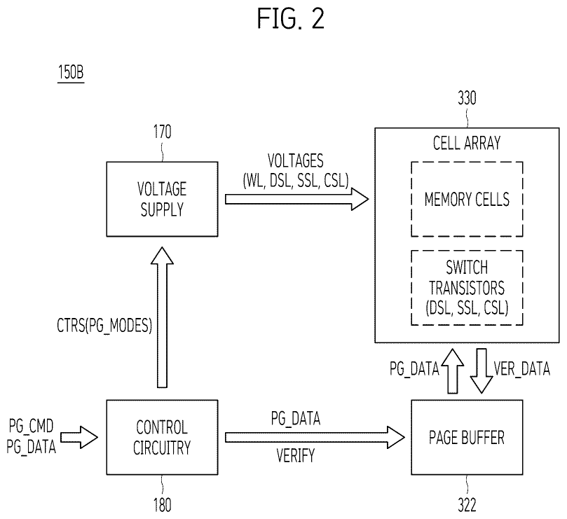

FIG. 2 illustrates a second memory according to an embodiment of the present disclosure.

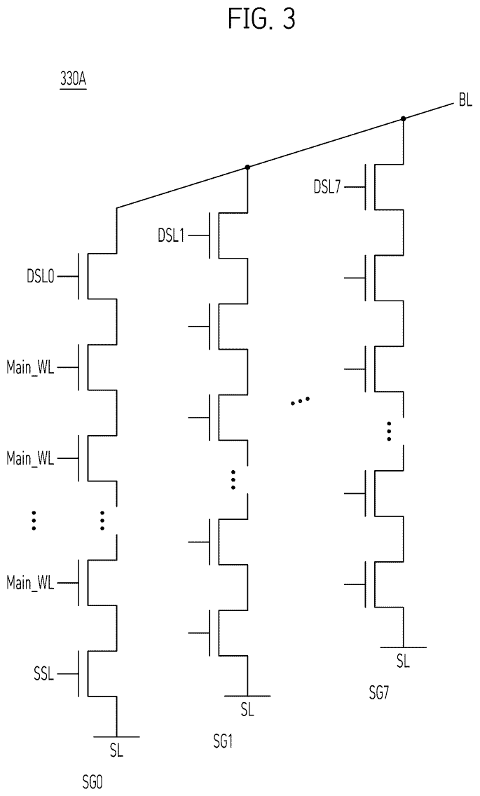

Referring to FIG. 2, the second memory device 150B can include the cell array 330. The cell array 330 can have a two-dimensional structure or a three-dimensional structure. The cell array 330 can include a plurality of memory cells capable of storing data and a plurality of switch transistors which are individually capable of controlling electrical connections between bit lines, source lines, etc., and the plurality of memory cells. The structure of the cell array 330 will be described later with reference to FIGS. 3 to 6.

The second memory device 150B can include the control circuitry 180. The control circuitry 180 can receive a program command PG_CMD input from an outside of the memory device. For example, the program command PG_CMD can be transferred from a memory controller or a host which is operatively engaged with the memory device 150B. The program command PG_CMD can be used for storing data in the cell array 330. According to an embodiment, another command for checking an operating state of the second memory device 150B other than the program command PG_CMD or performing an operation for improving the input/output performance, lifespan, wear rate, etc. of the second memory device 150B can be transmitted to the control circuitry 180.

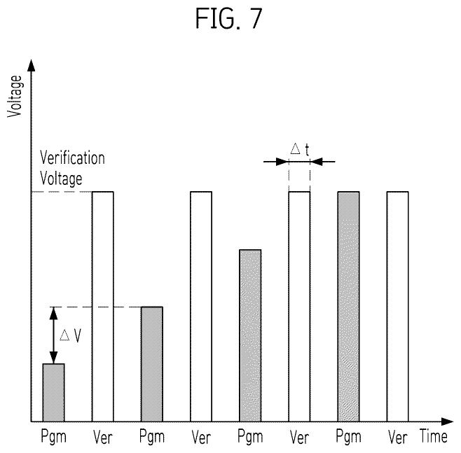

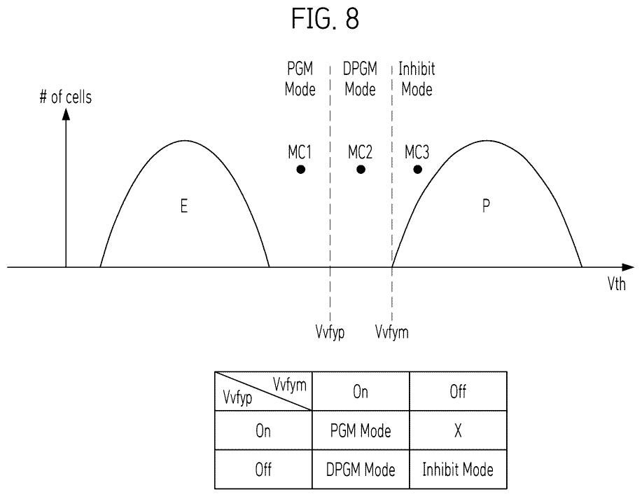

The control circuitry 180 that receives the program command PG_CMD can transmit a control signal CTRS to a voltage supply circuit 170. The voltage supply circuit 170 can generate at least one voltage in response to the control signal CTRS and transmit the at least one voltage to the cell array 330. For example, in response to the control signal CTRS, the voltage supply circuit 170 can generate or control a program voltage, a pass voltage, a verification voltage, etc. applied to the cell array 330. For example, the control circuitry 180 can determine whether to perform a program operation or a verification operation. Examples of the program operation and the verification operation will be described later with reference to FIG. 7. In addition, the control signal CTRS can vary depending on a program mode PG_MODES. An example of the program mode PG_MODES is described later with reference to FIG. 8.

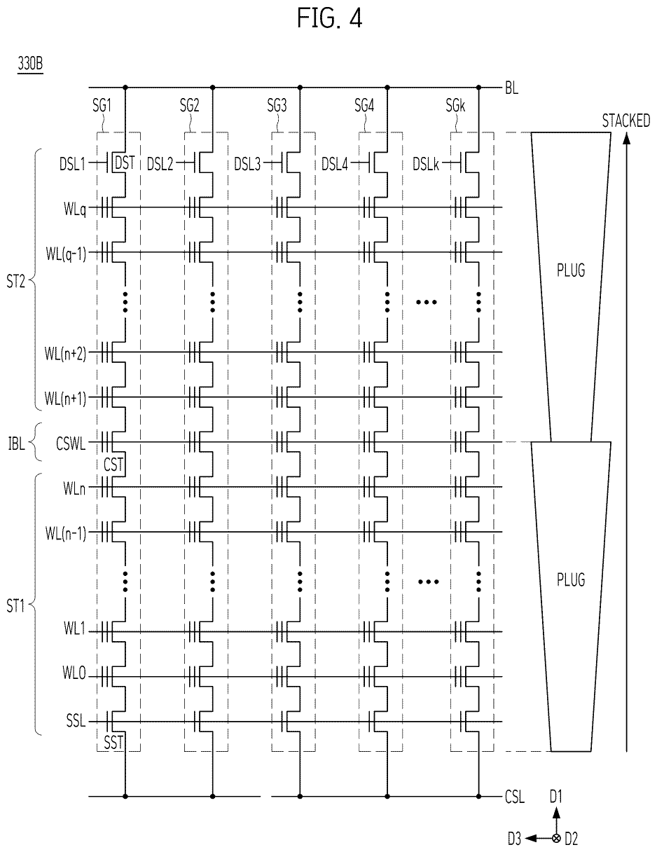

In the write operation based on the write command PG_CMD, the control circuitry 180 can control the voltage supply circuit 170 that generates and applies voltages to the cell array 330. The voltage supply circuit 170 can apply various levels of voltages to the cell array 330 through various lines. For example, based on the voltage(s) applied by the voltage supply circuit 170, each cell string included in the cell array 330 can be selected through a drain select line DSL in the cell array 330. In addition, the voltage supply circuit 170 can apply a program voltage or a pass voltage, etc. through a plurality of word lines WL in the cell array 330. The voltage supply circuit 170 can select a part of the cell array 330 for a program operation through a source selection line SSL, a central selection line (CSL), or a middle selection word line CSWL within the cell array 330 (see FIG. 4).

In addition, the control circuitry 180 can transfer program data PG_DATA to a page buffer 322. The page buffer 322 can include a plurality of latches, which can temporarily store data stored in, or to be stored in, each memory cell included in the cell array 330. For example, when multi-bit data is stored in each memory cell, each of the multi-bit data could be stored in each of the plurality of latches. According to an embodiment, based on a program operation scheme (e.g., a foggy-fine programming method, a binary programming method, etc.), the control circuitry 180 can store, in the page buffer 322, a value corresponding to a data bit (e.g., LSB data, MSB data, etc.) stored in each memory cell within the cell array 330.

The page buffer 322 and the cell array 330 can be coupled via a bit line BL (see FIG. 3). Data can be programmed in a memory cell to which a program voltage is applied based on a value stored in the page buffer 322. When the data is programmed in each memory cell, the control circuitry 180 can verify the data stored in the memory cell in the cell array 330. When the voltage supply circuit 170 can apply a voltage for verification via a word line during a verification operation, the memory cell coupled to the word line within the cell array 330 can output the stored data via the bit line. This verification data VER_DATA can be temporarily stored in the page buffer 322. The control circuitry 180 can check the data stored in the page buffer 322 to verify whether the program data PG_DATA is normally stored in the corresponding memory cell. This program operation and verification operation will be described later with reference to FIGS. 7 and 8.

A data storage capacity of the second memory device 150B can be determined based on the number of bits of data stored in each memory cell and the number of memory cells included in the cell array 330. In order to store more voluminous data, more memory cells can be included in the cell array 330. The cell array 330 can have a three-dimensional structure in which more memory cells can be integrated. In addition, as the number of memory cells increases, the number of memory cells coupled to a single word line WL or a single bit line BL could also increase.

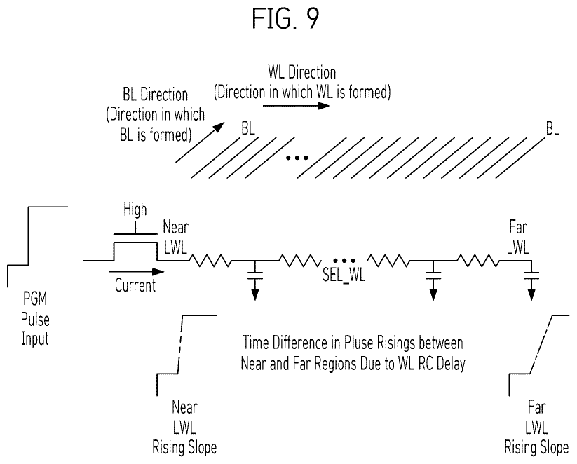

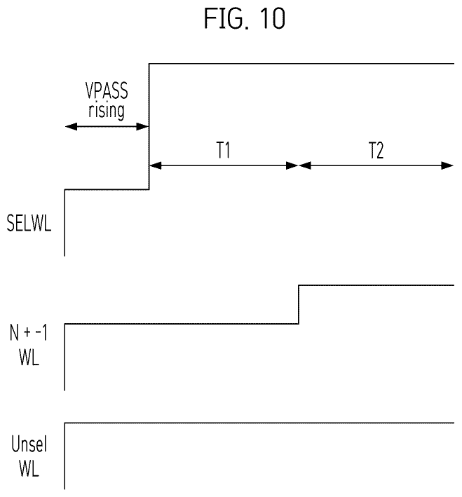

When performing the program operation and the verification operation, the voltage supply circuit 170 applies various levels of voltages such as a program voltage, a pass voltage, and a verification voltage through word lines WL. If a length of the word line WL becomes longer in order to integrate more memory cells, a voltage applied through the word line WL can be transmitted at different times to a first memory cell that is physically close to the voltage supply circuit 170 and a second memory cell that is physically far away from the voltage supply circuit 170. An issue due to a delay of the voltage applied through the word line WL will be described later with reference to FIG. 9. Further, a memory device and an operating method for the memory device to avoid the issue due to the delay of the voltage will be described later with reference to FIGS. 10 to 13.

FIG. 3 illustrates a structure of a first cell array 330A according to an embodiment of the present disclosure.

Referring to FIG. 3, the first cell array 330A can include a plurality of cell strings SG0, SG1, . . . , SG7. The plurality of cell strings SG0, SG1, . . . , SG7 can be coupled to a bit line BL. The connection between each of the plurality of cell strings SG0, SG1, . . . , SG7 and the bit line BL can be determined through a drain select line DSL0, DSL1, . . . , DSL7.

Among the plurality of cell strings SG0, SG1, . . . , SG7, a first cell string SG0 can include a plurality of memory cells, each memory cell capable of storing one-bit data or multi-bit data, a switching transistor coupled to a first drain select line DSL0, and a switching transistor coupled to a source select line SSL for controlling connection to a source line SL. According to an embodiment, each switching transistor can include plural transistors.

Plural memory cells can be coupled to plural word lines Main_WL. A single memory cell can be connected to a single word line among the plural word lines Main_WL. Based on the bit line BL and one of the plural word lines Main_WL, the control circuitry 180 can select a specific memory cell in a selected cell string within the first cell array 330A.

For example, the word line Main_WL can be coupled to one memory cell included in each of the plurality of cell strings SG0, SG1, . . . , SG7. As the number of the plurality of cell strings SG0, SG1, . . . , SG7 coupled to the word line Main_WL increases, the data storage capacity of the first cell array 330A can increase. Due to a delay (e.g., RC delay, etc.), voltages of various levels transmitted through the word line Main_WL can reach the first cell string SG0 and the eighth cell string SG7 at different times. As the number of the plurality of cell strings SG0, SG1, . . . , SG7 coupled to the word line Main_WL increases, the times at which the voltage is applied to a cell string (e.g., the first cell string SG0) closest to the voltage supply circuit 170 and a cell string (e.g., the eighth cell string SG7) farthest from the voltage supply circuit 170 can differ more significantly. According to an embodiment of the present disclosure, a memory device and an operating method of the memory device capable of avoiding or resolving an issue caused based on a phenomenon that the times differ at which the voltage is applied to each of the plurality of cell strings SG0, SG1, . . . , SG7 coupled to the word line Main_WL will be described below.

FIG. 4 illustrates a structure of a second cell array 330B according to an embodiment of the present disclosure.

Referring to FIG. 4, the second cell array 330B can have a structure including portions or layers stacked in a vertical direction D1. The second cell array 330B can include at least one memory block. Hereinafter, a direction substantially perpendicular to the upper surface of the substrate may be defined as a first direction D1, and two directions parallel to the upper surface of the substrate and intersecting each other may be defined as the second direction D2 and the third direction D3, individually. For example, the second direction D2 and the third direction D3 may intersect each other substantially perpendicularly. The first direction D1 may be referred to as a vertical direction, the second direction D2 may be referred to as a row direction, and the third direction D3 may be referred to as a column direction. The direction indicated by the arrow in the drawing and the direction opposite to it are described as the same direction.

For convenience of description, FIG. 4 shows NAND strings or cell strings SG1 to SGk connected to one bit line BL and one common source line CSL among the cell strings included in the memory block.

The memory block may include a plurality of cell strings SG1 to SGk connected between the same bit line (BL) and the common source line CSL. Each of the cell strings SG1 to SGk can include at least one source select transistor SST controlled by a source select line SSL, plural memory cells controlled by word lines WL, a central switching transistor CST disposed in an intermediate boundary layer IBL and controlled by a central switching word line CSWL, and a drain select transistor DST controlled by each drain select line DSL1, DSL2, DSL3, . . . , DSLk.

According to an embodiment, plural memory cells connected to at least one word line located at both ends of first and second stacks ST1, ST2 in the first direction D1 may be dummy cells. Any data may not be stored in the dummy cells. Further, according to an embodiment, the dummy cells may be used to store data having a smaller number of bits than other memory cells. According to an embodiment, the intermediate boundary layer IBL may include at least one gate line. One gate line corresponds to the central switching word line CSWL which can simultaneously control switching operations of the central switching transistors CST connected thereto. Although FIG. 4 illustrates a structure in which the first and second stacks ST1, ST2 are stacked, three or more stacks may be vertically stacked in the second cell array 330B. When a plurality of stacks are stacked, an intermediate boundary layer IBL may be formed and disposed between each two stacked stacks. The intermediate boundary layer IBL may include at least one switching transistor configured to couple memory cells in one stack of the two stacks to other memory cells in the other stack.

FIG. 4 shows an embodiment in which the source select transistors SST included in the plurality of cell strings SG1 to SGk are connected to the common select line CSL. However, according to an embodiment, a certain number of source select transistors could be coupled to each of plural source ground select lines.

Referring to FIGS. 3 to 4, the first or second cell array 330A, 330B can include a plurality of memory blocks arranged along a plurality of directions D1, D2, D3. In an embodiment, a memory block may be selected by the control circuitry 180 shown in FIG. 1. For example, a read voltage, a program voltage, or an erase voltage may be applied to a memory block and a word line selected by the control circuitry 180.

Each of the cell strings SG1 to SGk may include a plurality of switch transistors as well as a plurality of memory cells capable of storing data. Here, the plurality of switch transistors can include a drain select transistor DST, a source select transistor SST, and a central switching transistor CST. FIG. 4 shows an embodiment in which each of the cell strings SG1 to SGk includes one drain select transistor DST, one source select transistor SST, and one central switching transistor CST, respectively. However, according to an embodiment, each of the cell strings SG1 to SGk may include a plurality of drain select transistors DST, a plurality of source select transistors SST, or a plurality of intermediate switching transistors CST.

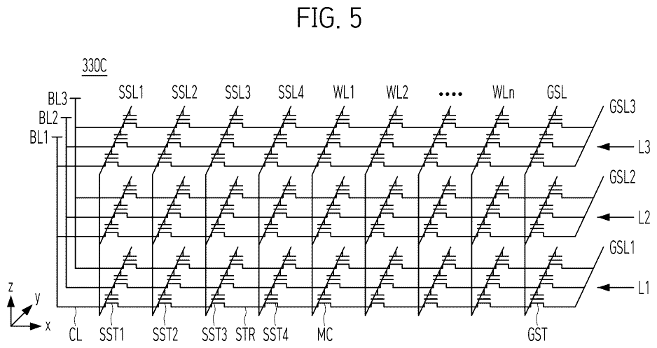

FIG. 5 illustrates a structure of a third cell array 330C according to an embodiment of the present disclosure.

Referring to FIGS. 4 and 5, the third cell array 330C may be stacked in the vertical direction (D1, Z) through a plurality of stacks ST1, ST2, as described in FIG. 4, and non-volatile memory cells can be placed in three-dimensional (3D) space. Specifically, FIG. 5 illustrates the third cell array 330C in a 3D non-volatile memory device according to an embodiment of the present disclosure.

The third cell array 330C may include a plurality of memory cells MC arranged in a cell string STR in a plurality of memory layers (e.g., three memory layers L1, L2, L3). The memory layers L1, L2, L3 are respectively connected to a plurality of bit lines BL1, BL2, BL3 through a first end of the plurality of channel lines CL and to the common source line CSL through a second end of the plurality of channel lines CL. The third cell array 330C may include a plurality of source select lines SSL1 to SSL4 connected to source select transistors SST1 to SST4. In addition, a plurality of word lines WL1 to WLn and a ground select line GSL may be connected to each of the memory layers L1, L2, L3. The plurality of source select lines SSL1 to SSL4, the plurality of word lines WL1 to WLn, and the ground select line GSL may be arranged in a direction that intersects a plurality of channel lines CL. Each of the plurality of channel lines may be described as the cell string STR. Each of the cell strings STR may include the source select transistors SST1 to SST4 respectively connected to the plurality of source select lines SSL1 to SSL4. The ground select line GSL may be grounded to turn off the ground selection transistor GST.

The plurality of word lines WL1 to WLn may each be connected to control gates of memory cells arranged in a column direction. Each of the plurality of bit lines BL1 to BL3 may be connected to one end of the source select transistors. A plurality of memory cells having control gate electrodes connected to each word line WL1 to WLn in the row direction can configure a page, which is a unit for storing data or a data entry. The number of pages could be changed or determined depending on a storage capacity of the memory cells.

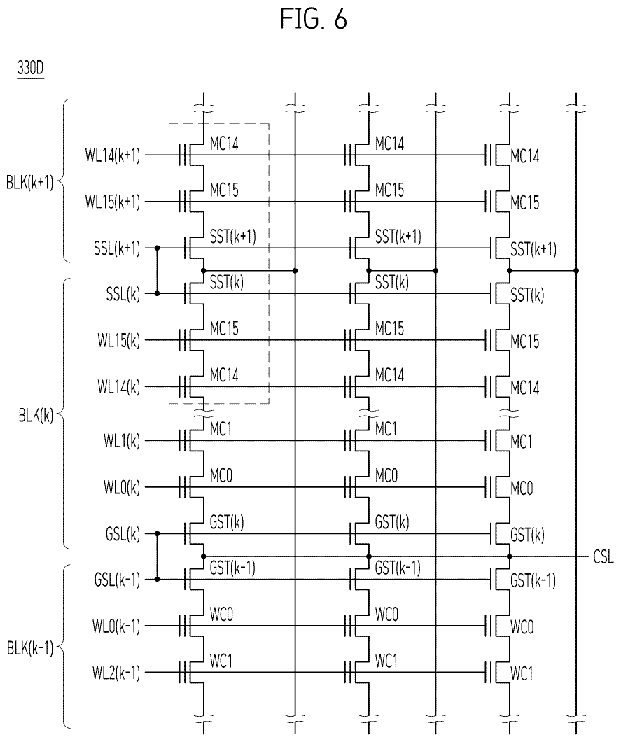

FIG. 6 illustrates a structure of a fourth cell array 330D according to an embodiment of the present disclosure. Specifically, FIG. 6 describes an internal configuration of the fourth cell array 330D.

Referring to FIG. 6, the fourth cell array 330D may include a plurality of memory blocks BLK(k+1), BLK(k), BLK(k−1). FIG. 6 illustrates three memory blocks BLK(k+1), BLK(k), BLK(k−1), but the fourth cell array 330D can include a plurality of memory blocks arranged in two or three dimensions. In FIG. 6, each memory block BLK(k+1), BLK(k), BLK(k−1) has plural memory cells coupled to 16 word lines WL0 to WL15. The 16 word lines WL0 to WL15 and a ground select line GSL in a direction perpendicular to a row or a bit line could be placed in parallel. However, the number of word lines included in each memory block may vary depending on an embodiment. Each memory block BLK(k+1), BLK(k), BLK(k−1) may include a cell string corresponding to each bit line. In a memory block BLK(k), each cell string may be connected to a source select transistor SST(k) and a ground select transistor GST(k) coupled to the corresponding bit line. The cell string may include 16 memory cells MC15 to MC0 connected in series between a common source line CSL and the string and ground select transistors SST(k), GST(k). The number of memory cells included in the cell string may correspond to the number of word lines. The source select transistor SST(k), the memory cells MC15 to MC0, and the ground select transistor GST(k) are individually connected to a source select line SSL(k), the word lines WL15 to WL0, and a ground select line GSL(k).

Referring to FIGS. 1 to 6, as the memory device 150A, 150B is designed to store more data, source select lines of adjacent memory blocks arranged in two or three dimensions may be electrically connected to each other. Further, the ground select lines for the adjacent memory blocks may be electrically connected to each other. For example, the source select line SSL(k) of the memory block BLK(k) may be electrically connected to the source select line SSL(k+1) of the adjacent memory block BLK(k+1). Further, adjacent string/ground select transistors along a bit line can share a contact to achieve electrical connection between adjacent string/ground select lines.

When designed to share a ground select line or a cell string between adjacent memory blocks, the disturb effect resulting from a read or write operation performed on a specific memory block can affect adjacent memory blocks (e.g., memory blocks with shared cell strings but not selected). Here, a scheme in which cell strings are shared between adjacent memory blocks can include a structure in which cell strings share a same component using an electrode or a functional layer such as any area or any semiconductor layer stacked on the semiconductor substrate or a body electrode formed in a trench of the semiconductor substrate where the cell strings are formed. Additionally, when designed to share a ground select line or a cell string for adjacent memory blocks, the disturb effect due to the read or write operation performed on a specific memory block among the adjacent memory blocks may be greater than a case where the cell string is not shared by the adjacent memory blocks. There is a difference in the read disturb effect according to a read operation on an open memory block depending on whether a cell string is shared by adjacent memory blocks of the memory device 150A, 150B.

Referring to FIGS. 1 to 6, to store more data in the memory device 150A, 150B, more memory cells may be integrated in a three-dimensional space. As the number of memory cells increases, the number of various control lines (e.g., word lines, drain select lines, source select lines, etc.) connected to the memory cells also increases. As the number of control lines increases, each control line could be layered to improve efficiency and enhance performance. Herein, layering can mean that the memory device 150 is designed to divide the first, second, third, or fourth cell array 330A, 330B, 330C, 330D into preset areas and use some layered control lines only in the divided areas.

FIG. 7 illustrates a program operation and a verification operation according to an embodiment of the present disclosure.

Referring to FIG. 7, after the program voltage application operation Pgm is performed during an incremental step pulse program (ISPP) operation, the memory device 150A, 150B performs a verification operation Ver corresponding to the program voltage application operation Pgm. Each program voltage application operation Pgm can increase the threshold voltage VTH of the non-volatile memory cell. For example, each program voltage application operation Pgm increases the threshold voltage VTH of the non-volatile memory cell by the first potential difference ΔV. After the program voltage application operation Pgm is performed, the threshold voltage VTH of the non-volatile memory cell may be compared with a verification voltage in the verification operation. When the threshold voltage VTH of the non-volatile memory cell is less than the verification voltage, the next program voltage application operation Pgm may be performed again to add more electrons into a floating gate of the non-volatile memory cell. Thereafter, the verification operation Ver is performed in response to the corresponding program voltage application operation Pgm. The repeated program voltage application operation Pgm may be performed until the threshold voltage VTH of the non-volatile memory cell reaches a target voltage (e.g., a verification voltage).

According to an embodiment, the number of repetitions of the program voltage application operation Pgm and the verification operation Ver may vary depending on a standby time or delay time, power consumption, accuracy, and the like. When the threshold voltage VTH of the non-volatile memory cell is finely increased through the program voltage application operation Pgm, accuracy of the program voltage application operation can be increased. However, delay time and power consumption can be longer and greater as a greater number of program voltage application operations can be performed. On the other hand, when the threshold voltage VTH of the non-volatile memory cell is greatly increased through each program voltage application operation Pgm, power consumption and operation time of the program voltage application operation Pgm may be increased and shorter. The operation times Δt of the program voltage application operation Pgm and the verify operation Ver may vary according to a goal of each program voltage application operation Pgm (e.g., a change of the threshold voltage VTH).

For example, in a memory device including a triple-level non-volatile memory cell TLC, the program voltage application operation Pgm and the verify operation Ver may be differently performed based on purpose and procedure of programming data in the least significant bit LSB, the center significant bit CSB and the most significant bit MSB of the memory cell. The memory device including a triple level non-volatile memory cell TLC has been described as an example, but the above-described program operation can also be applied to a memory device including a quadruple level non-volatile memory cell (QLC) for storing 4-bit data or a non-volatile memory cell capable of storing 5 or more bit data.

According to an embodiment, for each program loop during the ISPP operation, a voltage level of the program pulse applied to the non-volatile memory cell in the program voltage application operation Pgm may be gradually increased by a preset voltage ΔV. However, a voltage level of the verification pulse applied to the non-volatile memory cell in the verification operation Ver corresponding to the program voltage application operation Pgm may be substantially the same (i.e., not changed). In the verification operation Ver for each program loop, substantially the same verification pulse is applied to the non-volatile memory cell, but the time Δt for applying the verification pulse may vary. Moreover, when the verification operation is performed by reflecting a noise generated according to operating characteristics of the memory device 150, the memory device 150 may change or adjust a voltage level of the verification pulse.

FIG. 8 illustrates a program operation mode according to an embodiment of the present disclosure. In FIG. 8, a non-volatile memory cell can store single-bit (1-bit) data. The memory device 150A, 150B may be controlled such that a threshold voltage of the non-volatile memory cell becomes one of an erase state E or a program state P. When the incremental step pulse programming (ISPP) operation is performed as described with reference to FIG. 7, the threshold voltage of the non-volatile memory cell may be changed from the erase state E to the program state P. Referring to FIG. 7, a verification operation can be performed after a program pulse is applied.

Referring to FIG. 8, the verification operation may use two verification voltages Vvfp, Vvfym. Specifically, a data program operation supporting a double verify program (DPGM) operation may perform a verify operation with two different levels of verification voltage during a verify operation. Through the verification operation using two different verification voltage levels, a degree to which the non-volatile memory cell is programmed in response to a next program pulse may be adjusted. For example, the memory device 150A, 150B can determine an amount of change in the threshold voltage that could be caused by a next program pulse.

According to an embodiment, the verification voltage may include a pre-verification voltage Vvfyp and a main verification voltage Vvfym. Here, the main verification voltage Vvfym may be a verification voltage corresponding to a target state of the data program operation, and the pre-verification voltage Vvfyp has a level less than the main verification voltage Vvfym. In the verification operation, the pre-verification voltage Vvfyp can be used for checking a degree to which the data program operation is performed on a non-volatile memory cell. When it is checked by the verification operation using the main verification voltage Vvfym that a threshold voltage of the non-volatile memory cell is changed with the program state P, the non-volatile memory cell does not need to be programmed further by a next program pulse. Also, when a threshold voltage of the non-volatile memory cell is less than the pre-verification voltage Vvfyp, the non-volatile memory cell may be programmed by the next program pulse. If the threshold voltage of the non-volatile memory cell is in a range between the pre-verification voltage Vvfyp and the main verification voltage Vvfym, the non-volatile memory cell could be programmed too much (e.g., the threshold voltage of the non-volatile memory cell may rise too much, i.e., overprogramming) when normally programmed by the next program pulse. Thus, the memory device 150A, 150B could reduce an amount of change in the threshold voltage. In this case, the memory device 150A, 150B may control or adjust the degree to which the non-volatile memory cell is programmed (e.g., the amount of change in the threshold voltage) while the next program pulse is applied.

Referring to FIG. 8, when a plurality of non-volatile memory cells is programmed by a program pulse and then a verification operation is performed using the pre-verification voltage Vvfyp and the main verification voltage Vvfym, the plurality of non-volatile memory cells can be in three different states MC1, MC2, MC3. For a non-volatile memory cell having a first state MC1 less than the pre-verification voltage Vvfyp, the memory device 150A, 150B may apply a next program pulse to induce a change of threshold voltage of the corresponding memory cell by an amount or a shift corresponding to the next program pulse. Such a general program mode (PGM Mode) may be referred to as a first program mode. On the other hand, if a non-volatile memory cell has a third state MC3 greater than the main verification voltage Vvfym, the memory device 150A, 150B avoids the non-volatile memory cell from being further programmed by the next program pulse because the threshold voltage of the non-volatile memory cell has already reached the program state P. Herein, inhibiting the non-volatile memory cell from additionally programming may be referred to as a program inhibit mode. Further, when the non-volatile memory cell is in a second state MC2, a threshold voltage of the non-volatile memory cell may rise too much when the non-volatile memory cell is programmed in the first program mode (PGM mode). Thus, when the next program pulse is applied to the non-volatile memory cell in the second program mode (DPGM mode), a change amount of the threshold voltage may be less than the amount caused in the first program mode (PGM mode).

A degree to which the non-volatile memory cell is programmed (e.g., an amount of change in threshold voltage) may be determined based on a time for which the program pulse is applied, the number of times the program pulse is applied, and a potential difference between the program pulses. Although a single program pulse is applied to plural non-volatile memory cells connected to a single word line, the memory device 150A, 150B can change or adjust a threshold voltage change amount of each of the non-volatile memory cells connected to the single word line. For changing threshold voltages of the plural non-volatile memory cells by different amounts, the memory device 150A, 150B can change or adjust potentials of bit lines connected to the respective non-volatile memory cells connected to the single word line.

For example, during a period in which a program pulse is applied to the word line, a ground voltage is applied to a first bit line connected to a first memory cell of which threshold voltage is in the first state MC1, a program adjustment voltage greater than the ground voltage is applied to a second bit line connected to a second memory cell of which threshold voltage is in the second state MC2 and a program inhibit voltage greater than the program adjustment voltage is applied to a third bit line coupled to the third memory cell having the third state MC3. In this case, there are potential differences between the word line and the respective first to third bit lines. As a potential difference between a word line and a bit line connected to a non-volatile memory cell is lesser, a change amount of the threshold voltage of the non-volatile memory cell caused by the program pulse may be smaller. Further, when the potential difference between the word line and the bit line is less than a preset level, the non-volatile memory cell would be not programmed. Because the potential difference of the second memory cell having the second state MC2 is less than that of the first memory cell having the first state MC1, a degree to which the second memory cell is programmed by the next program pulse can be less than the degree of the first memory cell. Further, when the next program pulse is applied to the third memory cell and thus the potential difference between the program pulse and the program inhibit voltage applied to the third memory cell having the third state MC3 is less than the preset level, the third memory cell having the third state MC3 might not be programmed further despite the next program pulse.

Referring to FIG. 8, the program mode may be determined according to a verification result corresponding to a program operation performed on the non-volatile memory cell. The program mode may include the first program mode (PGM Mode), the second program mode (DPGM Mode), and the third program mode (PGM Inhibit Mode). For example, a verify pass may indicate that a non-volatile memory cell is read as an off cell in response to a verification voltage. A verify fail may indicate that the non-volatile memory cell is read as an on cell in response to the verification voltage. If a threshold voltage of the non-volatile memory cell is less than a verification voltage, the non-volatile memory cell is read as the on cell. But, if the threshold voltage is greater than or equal to the verification voltage, the non-volatile memory cell is read as the off cell.

Referring to FIG. 8, a non-volatile memory cell in which the program mode is the first program mode (PGM Mode) may be read as the on cell by both the pre verify voltage Vvfyp and the main verify voltage Vvfym. Another non-volatile memory cell in which the program mode is the second program mode (DPGM Mode) is read as the off cell by the pre-verification voltage Vvfyp and read as the on-cell by the main verify voltage Vvfym. Another non-volatile memory cell in which the program mode is the third program mode (PGM Inhibit Mode) may be read as the off cell by both the pre verify voltage Vvfyp and the main verify voltage Vvfym. Furthermore, because the pre-verification voltage Vvfyp has a level less than that of the main verification voltage Vvfym, there is no case when a non-volatile memory cell is read as the on cell by the pre-verification voltage Vvfyp and read as the off cell by the main verification voltage Vvfym.

FIG. 9 illustrates a delay regarding a voltage or a signal applied to a cell array according to an embodiment of the present disclosure.

Referring to FIG. 9, a plurality of bit lines BL can be arranged in a direction intersecting the word lines (BL direction, WL direction). Herein, how to transfer the voltage or the signal through a selected word line SEL_WL among the plurality of word lines is described.

The voltage supply circuit 170 described in FIG. 2 can apply a program pulse (PGM Pulse) to the selected word line SEL_WL. A control signal of a logic high level (High) can be applied to the gate of a switching element connecting the voltage supply circuit 170 and the selected word line SEL_WL. When the switching element is turned on, current can flow to the selected word line SEL_WL.

The program voltage or program pulse (PGM Pulse) can have a very high voltage level. For example, the program pulse (PGM Pulse) can have a voltage level greater than the pass voltage. As the number of memory cells connected to the selected word line SEL_WL increases, a length of the selected word line SEL_WL can become longer. A plurality of memory cells can be arranged between a region closest to the voltage supply circuit 170 or a switching element (e.g., Near Local Word Line, Near LWL) and a region farthest from the voltage supply circuit 170 or a switching element in the selected word line SEL_WL. The plurality of memory cells can be interpreted as components having capacitance. The selected word line SEL_WL can include a conductive material. However, the selected word line SEL_WL can have a resistance value. For this reason, a delay (e.g., RC Delay) can occur in the process in which the program pulse (PGM Pulse) is transmitted from the near region (Near LWL) to the farthest region (Far LWL) in the selected word line SEL_WL. Here, the delay (e.g., RC delay) can be estimated or calculated as a value obtained by multiplying the resistance (R) and the capacitance (C) values. The delay (e.g., RC delay) can show a signal or voltage delay in the electric signal transmission speed. When a voltage level transition occurs, such as a program voltage or a program pulse (PGM Pulse), the delay (e.g., RC delay) can occur due to the speed at which the selected word line SEL_WL is charged or discharged.

Due to the delay that occurs in the selected word line SEL_WL, a slope of the program pulse (Near LWL Rising Slope) in the closest region (Near LWL) and a slope of the program pulse (Far LWL Rising Slope) in the farthest region (Far LWL) can be different. The difference in the slope can cause the effective period of the program pulse (PGM Pulse) to be different. For example, when comparing a first memory cell located in the closest region (Near LWL) with a second memory cell located in the farthest region (Far LWL), the effective period of the program pulse (PGM Pulse) applied to the first memory cell can be longer than the effective period of the program pulse (PGM Pulse) applied to the second memory cell. This indicates that even if the same program pulse (PGM Pulse) is applied to the selected word line SEL_WL, the data programmed to the memory cell can differ depending on the location of the memory cell.

FIG. 10 illustrates a first program operation according to an embodiment of the present disclosure.

Referring to FIG. 10, during the first program operation, a pass voltage VPASS can be applied to a selected word line SELWL, a word line (N+−1 WL) adjacent to the selected word line SELWL, and an unselected word line (Unsel WL). For example, when a row address of the selected word line SELWL is ‘3’, a row address of the word line (N+−1 WL) adjacent to the selected word line SELWL can be ‘2’ or ‘4’. According to an embodiment, the selected word line SELWL and the adjacent word line (N+−1 WL) can be set differently. In addition, because the structure of the cell array may be different as described in FIGS. 3 to 6, the selected word line SELWL and the adjacent word line (N+−1 WL) can be determined corresponding to the cell array structure.

When a program voltage or program pulse is applied to the selected word line SELWL, the potential of the selected word line SELWL can rise from a voltage level of the pass voltage VPASS to a voltage level of the program voltage or program pulse (VPASS rising section).

Thereafter, after a first timing T1 has elapsed, the voltage level applied to the adjacent word line (N+−1 WL) adjacent to the selected word line SELWL can be raised by a preset level. For example, a first voltage having a preset level greater than the pass voltage can be applied to the adjacent word line (N+−1 WL). At this time, the voltage level applied to the unselected word line (Unsel WL) might not be changed.

Thereafter, the first voltage raised by the preset level from the pass voltage can be applied to the adjacent word line (N+−1 WL) adjacent to the selected word line SELWL during a second timing T2.

As described in FIG. 9, to compensate for the shortening of the effective period (e.g., the second time T2) of the program pulse in the memory cell located at the farthest region (Far LWL) from the voltage supply circuit 170 or the switching element in the selected word line SEL WL in the first program operation, a voltage level applied to the adjacent word line (N+−1 WL) adjacent to the selected word line SELWL can be increased by a preset level from the pass voltage VPASS. When the voltage level applied to the adjacent word line (N+−1 WL) adjacent to the selected word line SELWL is increased by a preset level, the slope of the program pulse (Far LWL Rising Slope) in the farthest region (Far LWL) can be improved due to the coupling phenomenon. Through this, it is possible to reduce the decrease in the effective period (e.g., the second timing T2) of the program pulse in the second memory cell located in the region (Far LWL) farthest from the voltage supply circuit 170 or the switching element in the selected word line SEL_WL.

However, in the first program operation, if the voltage level applied to the adjacent word line (N+−1 WL) adjacent to the selected word line SELWL is increased by a preset level, an effect due to the coupling phenomenon might occur not only in the second memory cell located in the region (Far LWL) farthest from the voltage supply circuit 170 or the switching element in the selected word line SELWL, but also in the first memory cell located in the region (Near LWL). Therefore, the effect of improving the delay that occurred in the region (Far LWL) farthest from the voltage supply circuit 170 or the switching element in the selected word line SELWL can be reduced.

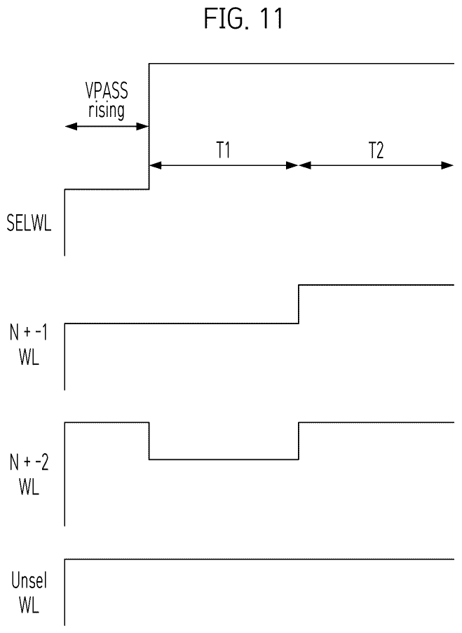

FIG. 11 illustrates a second program operation according to an embodiment of the present disclosure.

Referring to FIG. 11, the second program operation performed in the memory device 150A, 150B can be applicable to a wider region of the selected word line SELWL and the adjacent word lines (N+−1 WL, N+−2 WL) than the first program operation.

A method of applying the pass voltage VPASS and the program voltage or program pulse to the selected word line SELWL and the unselected word line (Unsel WL) during the second program operation can be the same as the first program operation. In addition, the method of controlling the voltage applied to the first adjacent word line (N+−1 WL) during the second program operation can be also substantially the same as the first program operation.

As compared to the first program operation, the second program operation can further include controlling a voltage applied to the second adjacent word line (N+−2 WL). For example, when a row address of the selected word line SELWL is ‘3’, a row address of the first adjacent word line (N+−1 WL) can be ‘2’ or ‘4’, and a row address of the second adjacent word line (N+−2 WL) can be ‘1’ or ‘5’. The second program operation can include a driving scheme through the first adjacent word line (N+−1 WL) by additionally controlling the second adjacent word line (N+−2 WL), so that the second program operation could improve the slope of the program pulse (Far LWL Rising Slope) in the farthest region (Far LWL).

In the second program operation, after the pass voltage is applied, a first voltage having a level greater than the pass voltage by a preset level could be applied to the second adjacent word line (N+−2 WL) before the program voltage or program pulse is applied to the selected word line SELWL (VPASS rising section). Thereafter, during the first timing T1 and the second timing T2, the first adjacent word line (N+−1 WL) and the second adjacent word line (N+−2 WL) could be driven or controlled in the same manner.

The second program operation can include applying a first voltage having a level greater than a voltage applied to the first adjacent word line (N+−1 WL) to the second adjacent word line (N+−2 WL) and then applying voltages of the same level to both the first adjacent word line (N+−1 WL) and the second adjacent word line (N+−2 WL). While a program voltage or a program pulse is applied to the selected word line SELWL, the coupling phenomenon between the selected word line SELWL and the first adjacent word line (N+−1 WL) could be reduced, thereby reducing the increase in the potential of the first adjacent word line (N+−1 WL). For example, by lowering the potential of the second adjacent word line (N+−2 WL) during the first timing T1, the potential of the first adjacent word line (N+−1 WL), which has risen or driven due to the coupling phenomenon with the selected word line SELWL, can be lowered.

During the second timing T2, the second program operation can include increasing the levels of the voltages applied to not only the first adjacent word line (N+−1 WL) but also the second adjacent word line (N+−2 WL). In this case, based on the coupling phenomenon, the slope of the program pulse (Far LWL Rising Slope) in the region (Far LWL) farthest from the selected word line SELWL could be improved (e.g., the slope becomes steeper or sharper).

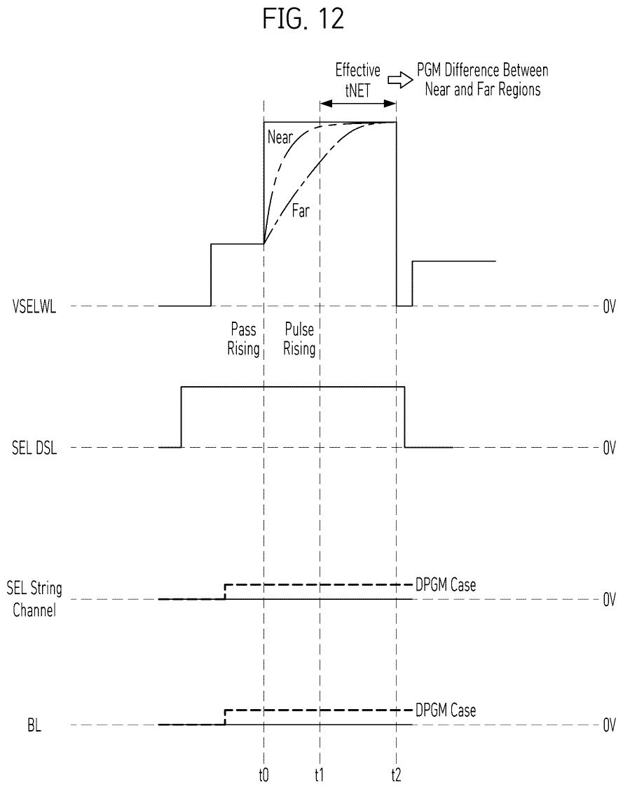

FIG. 12 illustrates a third program operation according to an embodiment of the present disclosure. In FIG. 12, the third program operation can include both an operation in the first program mode (PGM Mode) that induces a threshold voltage variation amount at a preset level described in FIG. 8 and an operation in the second program mode (DPGM Mode) that induces a less threshold voltage variation amount compared to the first program mode (PGM Mode).

Referring to FIG. 12, the third program operation can include controlling a voltage on a selected word line among a plurality of word lines (VSELWL) and controlling a voltage on a selected drain select line among a plurality of drain select lines (SEL DSL). Referring to FIGS. 3 to 6, the drain select line can select a cell string among the plurality of cell strings, while the word line can specify a memory cell in which data is programmed in the selected cell string. The third program operation can include activating the selected drain select line (SEL DSL) before the program pulse is applied (e.g., before a first time point t0), apply a pass voltage to the selected word line (Pass Rising), and apply a program voltage or a program pulse (Pulse Rising) at the first time point t0. At a third time point t2, a voltage level of the selected word line (VSELWL) can be lowered to 0 V. After the voltage level of the selected word line (VSELWL) is lowered to 0 V, the selected drain select line (SEL DSL) can be inactivated.

Referring back to FIG. 8, at least some of the selected memory cells can be programmed with data in the first program mode (PGM Mode), while at least some of the selected memory cells can be programmed with data in the second program mode (DPGM Mode). The first program mode (PGM Mode) or the second program mode (DPGM Mode) can be determined based on a potential difference of the cell string while the program voltage or program pulse is applied (e.g., from t0 to t2). For example, a bit line BL coupled to the memory cell programmed in the first program mode (PGM Mode) can be maintained at 0 V, while another bit line BL coupled to the memory cell programmed in the second program mode (DPGM Mode) can be maintained at a potential which is greater than 0 V by a preset level. The potential of the bit line BL can be transferred to the cell string selected by the selected drain select line (SEL DSL), so that a channel (e.g., SEL string channel) of the selected cell string can have a potential substantially similar to the bit line. A cell string corresponding to an unselected drain select line among the plurality of drain select lines becomes in a floating state, so that data might not be programmed in a memory cell included in the corresponding cell string.

The third program operation can include activating the drain select line of the cell string where data is to be programmed while the program voltage or program pulse is applied (e.g., from t0 to t2). The memory device can control the program mode (e.g., PGM 0V or DPGM#V which is greater than 0V) through the bit line BL and apply a high-level program voltage or program pulse to the selected word line. During this procedure, an effective period (e.g., Effective tNET) of the program voltage or program pulse can vary due to a delay (e.g., RC Delay) between the nearest region (Near) and the farthest region (Far) selected by the selected word line (SEL WL). For example, in the nearest region (Near), the effective period (Effective tNET) of the program voltage or program pulse can be secured from the second time point t1 to the third time point t2, whereas in the farthest region (Far), the program voltage or program pulse might be rising at the second time point t1. Accordingly, the effective period (Effective tNET) of the program voltage or program pulse can be reduced in the farthest region (Far). The third program operation might have difficulty in resolving the issue of shortening the effective period (Effective tNET) of the program pulse in a memory cell located in the farthest region (Far) from the voltage supply circuit 170 or a switching element used for coupling the selected word line (SEL WL) to the voltage supply circuit 170.

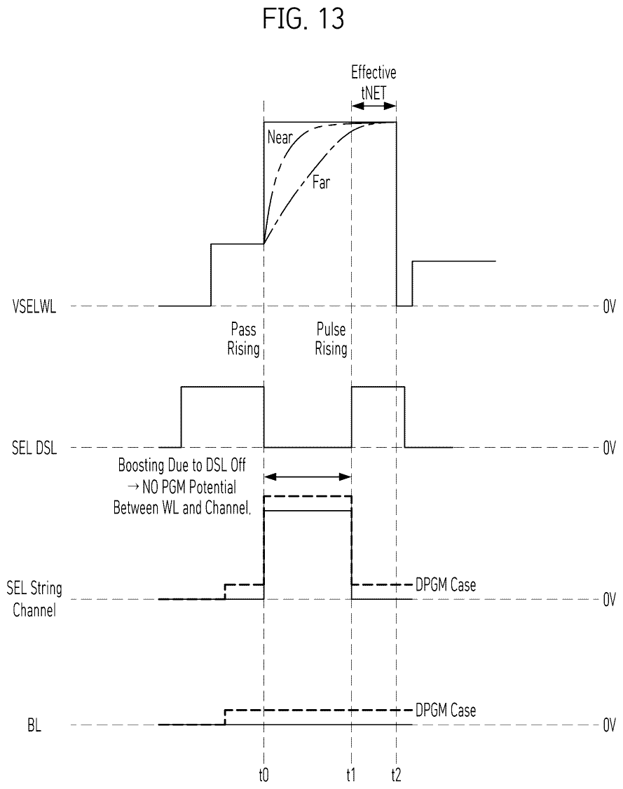

FIG. 13 illustrates a fourth program operation according to an embodiment of the present disclosure.

Referring to FIGS. 12 and 13, the third program operation and the fourth program operation can include a same scheme for controlling the potential of a selected word line among multiple word lines (VSELWL). Further, the third program operation and the fourth program operation can have a same scheme for controlling a potential difference of the bit line BL in the first program mode (PGM Mode) and the second program mode (DPGM Mode) while the program voltage or program pulse is applied (e.g., from t0 to t2).

Compared to the third program operation, the fourth program operation can include a different scheme for controlling the selected drain select line among the plural drain select lines (SEL DSL). As the control of the selected drain select line among the plural drain select lines (SEL DSL) changes, the potential of the channel of the selected cell string (SEL string channel) can change.

The fourth program operation can include inactivating the selected drain select line (SEL DSL) at the first time point t0 when the program voltage or program pulse is applied. When the selected drain select line (SEL DSL) becomes 0V at the first time point t0, the channel of the selected cell string (SEL string channel) can float (i.e., become in a floating state) so that the potential could be boosted. Thereafter, the selected drain select line (SEL DSL) is re-activated at the second time point t1. Here, the second time point t1 can indicate a time point at which the potential of the selected word line (VSELWL) in the farthest region (Far) from the voltage supply circuit 170 or the switching element can be sufficiently increased to a target level. The fourth program operation can secure a time period from the second time point t1 to the third time point t2 as the effective period (Effective tNET) of the program voltage or program pulse.

When the selected drain select line (SEL DSL) is inactivated from the first time point t0 to the second time point t1 and the channel of the selected cell string (SEL string channel) is floated, a potential difference (PGM potential) for a program operation might not be formed between selected word line (SEL WL) and the channel of the selected cell string. When plural cell strings coupled to the selected word line are floated, the difference in the effective section (Effective tNET) of the program voltage or program pulse could be avoided or reduced between the nearest area (Near) and the farthest area (Far) due to the delay (e.g., RC Delay) in the selected word line (SEL WL). For example, if the program voltage or program pulse sufficiently rises to the first memory cell located in the nearest area (Near) corresponding to the selected word line (SEL WL) before the second time point t1, data could not be programmed to the first memory cell because the selected drain select line (SEL DSL) is inactivated.

The selected drain select line (SEL DSL) can be activated after a sufficiently increased level of the program voltage or program pulse is applied to both the first memory cell located in the closest region (Near) and the second memory cell located in the farthest region (Far) from the voltage supply circuit 170 or the switching element (e.g., after the second time point t1). Thus, the effective period (Effective tNET) of the program voltage or program pulse for both the first memory cell and the second memory cell could be substantially the same.

Referring to FIG. 7 and FIG. 13, when there is no substantial difference in effective periods (Effective tNET) of the program pulse or operation times (Δt) of the program operation (Pgm) and the verification operation (Ver) between the closest region (Near) and in the farthest region (Far) from the voltage supply circuit 170 or the switching element, accuracy or efficiency of the program operation and the verification operation of the memory device could be improved. For example, if the effective period (Effective tNET) of the program voltage or the program pulse is substantially the same, the data (e.g., a range of the threshold voltage to be changed) programmed to the first memory cell and the second memory cell can be substantially the same in a same program mode. When the difference between the first memory cell located in the closest region (Near) and the second memory cell located in the farthest region (Far) from the voltage supply circuit 170 or the switching element is reduced, the accuracy of the program operation and the verification operation could be improved so that the operation efficiency of the memory device could be improved.

According to an embodiment, even if the channel of the selected cell string (SEL string channel) is floating while the selected drain select line (SEL DSL) is inactivated from the first time point t0 to the second time point t1, the potential of the channel of the selected cell string (SEL string channel) can be changed in response to the change in the potential applied to the bit line BL based on the first program mode (PGM Mode) or the second program mode (DPGM Mode).

According to an embodiment, the second time point t1 affecting the effective section (Effective tNET) of the program voltage or program pulse can be determined through a simulation or a test during the design or manufacturing process. Further, because it might be difficult through the simulation or the test to measure a time point when a sufficiently increased level of the program voltage or program pulse applied to the second memory cell located at the farthest region (Far) can be applied, the memory device can store a plurality of selectable time options for activating or inactivating the selected drain select line (SEL DSL). For example, the memory device can perform a program operation and a verification operation based on the plurality of selectable time options, and select a preferable time option corresponding to the operational state of the memory device based on the results of the program operation and the verification operation (e.g., success or failure of the operations and times spent on the operations).

A memory device according to an embodiment of the present disclosure can determine or adjust the effective period (Effective tNET) of the program voltage or program pulse by controlling activation and inactivation of the drain select line (SEL DSL) during at least a part of the region in which the program voltage or program pulse is applied, thereby reducing a difference or imbalance that might occur due to a delay in the program voltage or program pulse applied to a first memory cell located in the closest region (Near) and a second memory cell located in the farthest region (Far) from the voltage supply circuit 170 or a switching element. Because the accuracy and efficiency of the program operation and the verification operation are improved, the time spent on the program operation and the verification operation could be reduced.

As above described, according to an embodiment of the present disclosure, a memory device or a memory system can use a cell string selection signal to reduce or avoid an issue due to a delay caused by different distances from a voltage supply device, which is capable of applying at least one voltage through a word line, to each location of a plurality of memory cells coupled to the word line, thereby improving reliability or accuracy of program and verification operations performed within the memory device or the memory system.

According to an embodiment of the present disclosure, while applying a program voltage or a program pulse for programming data, voltage levels applied through a selected word line connected to a memory cell and an adjacent word line can be increased by a preset level, thereby reducing or eliminating an issue due to a delay caused by different distances from a voltage supply device capable of applying a voltage to each location of a plurality of memory cells coupled to the word line. A coupling effect from this scheme can improve the reliability or accuracy of the program operation and the verification operation performed within the memory device or the memory system.

In addition, a memory device or a memory system according to an embodiment of the present disclosure can substantially equalize and clearly set times for a program operation and a verification operation performed based on voltages applied to a plurality of memory cells, thereby improving the accuracy and efficiency of the program operation and the verification operation and reducing resources spent on the program operation performed within the memory device or the memory system.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods or operations of the computer, processor, controller, or other signal processing device, are described in detail, the code or instructions for implementing the operations of the method embodiments may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, generators, logic, interfaces, decoders, drivers, and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, generators, logic, interfaces, decoders, drivers, and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, generators, logic, interfaces, decoders, drivers, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods or operations of the computer, processor, microprocessor, controller, or other signal processing device, are described in detail, the code or instructions for implementing the operations of the method embodiments may transform the computer, processor, controller, or other signal processing device into a special-purpose processor for performing the methods described herein.

While the embodiments of the present disclosure have been illustrated and described with respect to the specific embodiments, it will be apparent to those skilled in the art in light of the present disclosure that various changes and modifications may be made to the embodiments without departing from the spirit and scope of the present disclosure. Furthermore, the embodiments may be combined to form additional embodiments.

What is claimed is:

1. A memory device comprising:
a cell array comprising a plurality of cell strings coupled to a word line and a drain select line; and
control circuitry configured to:
apply a program voltage to the word line during a program time period, and
control the drain select line to avoid programming data in plural memory cells included in the plurality of cell strings during a partial time length in the program time period.

2. The memory device according to claim 1, wherein the partial time length comprises a delay time of the program voltage which reaches a second cell string farthest from the control circuit after applied through the word line.

3. The memory device according to claim 1, wherein the plurality of cell strings includes a first cell string closest to the control circuitry and a second cell string farthest from the control circuitry, and effective periods for programming the data in the first cell string and the second cell string are substantially equal to each other.

4. The memory device according to claim 3, wherein each effective period is 50% or less of the program time period.

5. The memory device according to claim 1, wherein the control circuity is configured to inactivate the drain select line during the partial time length.

6. The memory device according to claim 1, wherein the partial time length is determined based on a number of the plurality of cell strings coupled to the word line.

7. The memory device according to claim 1, wherein the program voltage has a voltage level greater than a pass voltage applied to other word lines adjacent to the word line, and
the control circuitry is configured to apply the program voltage to the word line after applying the pass voltage to the other word lines.

8. The memory device according to claim 7, wherein the control circuitry is configured to inactivate the drain select line while the pass voltage is applied.

9. The memory device according to claim 1, wherein the control circuitry is configured to control the drain select line to avoid verifying the data programmed in the plural memory cells during a partial time period of a verification time period in which a verification voltage is applied to the word line.

10. A method for operating a memory device, the method comprising:
applying a program voltage to a plurality of memory cells through a word line during a program time period; and
controlling a drain select line to avoid programming data in the plurality of memory cells included in a plurality of cells strings during a partial time length in the program time period.

11. The method according to claim 10, wherein the plurality of cell strings includes a first cell string closest to the control circuitry and a second cell string farthest from the control circuitry, and effective periods for programming the data in the first cell string and the second cell string are substantially equal to each other.

12. The method according to claim 10, wherein the partial time length is determined based on a number of the plurality of cell strings coupled to the word line.

13. The method according to claim 10, wherein controlling the drain select line comprises:
inactivating the drain select line during the partial time length.

14. The method according to claim 10, wherein applying the program voltage comprises:
applying a pass voltage to plural word lines and inactivating the drain select line while the pass voltage is applied; and
applying the program voltage to the word line selected among the plural word lines.

15. The method according to claim 10, further comprising:
applying a verification voltage to the word line; and
controlling the drain select line to avoid verifying the data in the plurality of memory cells included in the plurality of cells strings during a partial time length of a verification time period in which the verification voltage is applied to the word line.

16. A memory device comprising:
a plurality of drain select lines individually coupled to each of a plurality of cell strings;
at least one word line coupled to the plurality of cell strings; and
control circuitry configured to;
apply a program voltage to the word line during a program time period, and
control the plurality of drain select line to avoid programming data in plural memory cells included in the plurality of cell strings during a partial time length in the program time period.

17. The memory device according to claim 16, wherein the plurality of cell strings includes a first cell string closest to the control circuitry and a second cell string farthest from the control circuitry, and effective periods for programming the data in the first cell string and the second cell string are substantially equal to each other.

18. The memory device according to claim 17, wherein the partial time length is determined based on a number of the plurality of cell strings coupled to the word line.

19. A memory device comprising:
a plurality of word lines coupled to a plurality of cell strings; and
control circuitry configured to select a word line among the plurality of word lines and apply a first voltage to at least one adjacent word line adjacent to the word line before applying a program voltage to the word line, the first voltage having a level greater than a pass voltage.

20. The memory device according to claim 19, wherein the at least one adjacent word line comprises a first word line and a second word line, which is closer to the word line than the first word line, and
wherein the control circuitry is configured to:
apply the pass voltage to the second word line before applying the program voltage to the word line and during a preset time period after applying the program voltage to the word line;
apply the first voltage to the first word line before applying the program voltage to the word line; and
apply the pass voltage to the first word line during the preset time period.
